(19) United States
(12) Patent Application Publication
(10) Pub. No.: US 2008/0238531 A1
(43) Pub. Date: Oct. 2, 2008

(54) SYSTEMS, DEVICES, AND METHODS FOR CONTROLLABLY COUPLING QUBITS

(76) Inventor: Richard G. Harris, Vancouver (CA)

Correspondence Address: SEED INTELLECTUAL PROPERTY LAW GROUP PLLC, 701 FIFTH AVE, SUITE 5400, SEATTLE, WA, 98104, US

(21) Appl. No.: 12/017,995

(22) Filed: Jan. 22, 2008

Related U.S. Application Data
(60) Provisional application No. 60/886,253, filed on Jan. 23, 2007.

(51) Int. Cl. H03K 3/38

(52) U.S. Cl. 327/528

(57) ABSTRACT

A coupling system may include an rf-SQUID having a loop of superconducting material interrupted by a compound Josephson junction; and a first magnetic flux inductor configured to selectively provide a mutual inductance coupling the first magnetic flux inductor to the compound Josephson junction, wherein the loop of superconducting material positioned with respect to a first and second qubits to provide respective mutual inductance coupling therebetween. The coupling system may further include a second magnetic flux inductor configured to selectively provide a second magnetic flux inductor mutual inductance coupling the second magnetic flux inductor to the compound Josephson junction. A superconducting processor may include the coupling system and two or more qubits. A method may include providing the first, the second and the third mutual inductances.

### CROSS-REFERENCE TO RELATED APPLICATION

This application claims the benefit under 35 U.S.C. § 119(e) of U.S. Provisional Patent Application No. 60/886,253 filed Jan. 23, 2007, this provisional application is incorporated herein by reference in their entirety.

### BACKGROUND

1. Field

The present disclosure generally relates to superconducting computing, for example analog or quantum computing employing processors that operate at temperatures at which materials superconduct.

2. Description of the Related Art

A Turing machine is a theoretical computing system, described in 1936 by Alan Turing. A Turing machine that can efficiently simulate any other Turing machine is called a Universal Turing Machine (UTM). The Church-Turing thesis states that any practical computing model has either the equivalent or a subset of the capabilities of a UTM.

A quantum computer is any physical system that harnesses one or more quantum effects to perform a computation. A quantum computer that can efficiently simulate any other quantum computer is called a Universal Quantum Computer (UQC).

In 1981 Richard P. Feynman proposed that quantum computers could be used to solve certain computational problems more efficiently than a UTM and therefore invalidate the Church-Turing thesis. See e.g., Feynman R. P., “Simulating Physics with Computers”, International Journal of Theoretical Physics, Vol. 21 (1982) pp. 467-488. For example, Feynman noted that a quantum computer could be used to simulate certain other quantum systems, allowing exponentially faster calculation of certain properties of the simulated quantum system than is possible using a UTM.

### Approaches to Quantum Computation

There are several general approaches to the design and operation of quantum computers. One such approach is the “circuit model” of quantum computation. In this approach, qubits are acted upon by sequences of logical gates that are the compiled representation of an algorithm. Circuit model quantum computers have several serious barriers to practical implementation. In the circuit model, it is required that qubits remain coherent over time periods much longer than the single-gate time. This requirement arises because circuit model quantum computers require operations that are collectively called quantum error correction in order to operate. Quantum error correction cannot be performed without the circuit model quantum computer's qubits being capable of maintaining quantum coherence over time periods on the order of 1,000 times the single-gate time. Much research has been focused on developing qubits with sufficient coherence to form the basic elements of circuit model quantum computers. See e.g., Shor, P. W. “Introduction to Quantum Algorithms”, arXiv.org:quant-ph/0005003 (2001), pp. 1-27. The art is still hampered by an inability to increase the coherence of qubits to acceptable levels for designing and operating practical circuit model quantum computers.

Another approach to quantum computation, involves using the natural physical evolution of a system of coupled quantum systems as a computational system. This approach does not make use of quantum gates and circuits. Instead, the computational system starts from a known initial Hamiltonian with an easily accessible ground state and is controllably guided to a final Hamiltonian whose ground state represents the answer to a problem. This approach does not require long qubit coherence times. Examples of this type of approach include adiabatic quantum computation, cluster-state quantum computation, one-way quantum computation, quantum annealing and classical annealing, and are described, for example, in Farhi, E. et al., “Quantum Adiabatic Evolution Algorithms versus Simulated Annealing” arXiv.org:quant-ph/0201031 (2002), pp 1-24.

### Qubits

As mentioned previously, qubits can be used as fundamental elements in a quantum computer. As with bits in UTMs, qubits can refer to at least two distinct quantities; a qubit can refer to the actual physical device in which information is stored, and it can also refer to the unit of information itself, abstracted away from its physical device.

Qubits generalize the concept of a classical digital bit. A classical information storage device can encode two discrete states, typically labeled “0” and “1”. Physically these two discrete states are represented by two different and distinguishable physical states of the classical information storage device, such as direction or magnitude of magnetic field, current, or voltage, where the quantity encoding the bit state behaves according to the laws of classical physics. A qubit also contains two discrete physical states, which can also be labeled “0” and “1”. Physically these two discrete states are represented by two different and distinguishable physical states of the quantum information storage device, such as direction or magnitude of magnetic field, current, or voltage, where the quantity encoding the bit state behaves according to the laws of quantum physics. If the physical quantity that stores these states behaves quantum mechanically, the device can additionally be placed in a superposition of 0 and 1. That is, the qubit can exist in both a “0” and “1” state at the same time, and so can perform a computation on both states simultaneously. In general, N qubits can be in a superposition of 2^{N} states. Quantum algorithms make use of the superposition property to speed up some computations.

In standard notation, the basis states of a qubit are referred to as the |0) and |1) states. During quantum computation, the state of a qubit, in general, is a superposition of basis states so that the qubit has a nonzero probability of occupying the |0) basis state and a simultaneous nonzero probability of occupying the |1) basis state. Mathematically, a superposition of basis states means that the overall state of the qubit, which is denoted |ψ>), has the form |>=a|0>+b|1, where a and b are coefficients corresponding to the probabilities |a|² and |b|², respectively. The coefficients a and b each have real and imaginary components, which allows the phase of the qubit to be characterized. The quantum nature of a qubit is largely derived from its ability to exist in a coherent superposition of basis states and for the state of the qubit to have a phase. A qubit will retain this ability to exist as a coherent superposition of basis states when the qubit is sufficiently isolated from sources of decoherence.

To complete a computation using a qubit, the state of the qubit is measured (i.e., read out). Typically, when a measurement of the qubit is performed, the quantum nature of the qubit is temporarily lost and the superposition of basis states collapses to either the |0> basis state or the |1> basis state and thus regaining its similarity to a conventional bit. The actual state of the qubit after it has collapsed depends on the probabilities |a|² and |b|² immediately prior to the readout operation.

### Superconducting Qubits

There are many different hardware and software approaches under consideration for use in quantum computers. One hardware approach uses integrated circuits formed of superconducting materials, such as aluminum or niobium. The technologies and processes involved in designing and fabricating superconducting integrated circuits are similar to those used for conventional integrated circuits.

Superconducting qubits are a type of superconducting device that can be included in a superconducting integrated circuit. Superconducting qubits can be separated into several categories depending on the physical property used to encode information. For example, they may be separated into charge, flux and phase devices, as discussed in, for example Makhlin et al., 2001, Reviews of Modern Physics 73, pp. 357-400. Charge devices store and manipulate information in the charge states of the device, where elementary charges consist of pairs of electrons called Cooper pairs. A Cooper pair has a charge of 2e and consists of two electrons bound together by, for example, a phonon interaction. See e.g., Nielsen and Chuang, Quantum Computation and Quantum Information, Cambridge University Press, Cambridge (2000), pp. 343-345. Flux devices store information in a variable related to the magnetic flux through some part of the device. Phase devices store information in a variable related to the difference in superconducting phase between two regions of the phase device. Recently, hybrid devices using two or more of charge, flux and phase degrees of freedom have been developed. See e.g., U.S. Pat. No. 6,838,694 and U.S. Patent Application No. 2005-0082519.

### Computational Complexity Theory

In computer science, computational complexity theory is the branch of the theory of computation that studies the resources, or cost, of the computation required to solve a given computational problem. This cost is usually measured in terms of abstract parameters such as time and space, called computational resources. Time represents the number of steps required to solve a problem and space represents the quantity of information storage required or how much memory is required.

Computational complexity theory classifies computational problems into complexity classes. The number of complexity classes is ever changing, as new ones are defined and existing ones merge through the contributions of computer scientists. The complexity classes of decision problems include:

1. P—The complexity class containing decision problems that can be solved by a deterministic UTM using a polynomial amount of computation time;

2. NP (“Non-deterministic Polynomial time”)—The set of decision problems solvable in polynomial time on a non-deterministic UTM. Equivalently, it is the set of problems that can be “verified” by a deterministic UTM in polynomial time;

3. NP-hard (Nondeterministic Polynomial-time hard)—A problem H is in the class NP-hard if and only if there is an NP-complete problem L that is polynomial time Turing-reducible to H. That is to say, L can be solved in polynomial time by an oracle machine with an oracle for H;

4. NP-complete—A decision problem C is NP-complete if it is complete for NP, meaning that:
(a) it is in NP and
(b) it is NP-hard,
   i.e., every other problem in NP is reducible to it. “Reducible” means that for every problem L, there is a polynomial-time reduction, a deterministic algorithm which transforms instances I ε L into instances c ε C, such that the answer to c is YES if and only if the answer to I is YES. To prove that an NP problem A is in fact an NP-complete problem it is sufficient to show that an already known NP-complete problem reduces to A.

Decision problems have binary outcomes. Problems in NP are computation problems for which there exists a polynomial time verification. That is, it takes no more than polynomial time (class P) in the size of the problem to verify a potential solution. It may take more than polynomial time, however, to find a potential solution. NP-hard problems are at least as hard as any problem in NP.

Optimization problems are problems for which one or more objective functions are minimized or maximized over a set of variables, sometimes subject to a set of constraints. For example, the Traveling Salesman Problem (“TSP”) is an optimization problem where an objective function representing, for example, distance or cost, must be optimized to find an itinerary, which is encoded in a set of variables representing the optimized solution to the problem. For example, given a list of locations, the problem may consist of finding the shortest route that visits all locations exactly once. Other examples of optimization problems include Maximum Independent Set, integer programming, constraint optimization, factoring, prediction modeling, and k-SAT. These problems are abstractions of many real-world optimization problems, such as operations research, financial portfolio selection, scheduling, supply management, circuit design, and travel route optimization. Many large-scale decision-based optimization problems are NP-hard. See e.g., “A High-Level Look at Optimization: Past, Present, and Future” e-Optimization.com, 2000.

Simulation problems typically deal with the simulation of one system by another system, usually over a period of time. For example, computer simulations can be made of business processes, ecological habitats, protein folding, molecular ground states, quantum systems, and the like. Such problems often include many different entities with complex inter-relationships and behavioral rules. In Feynman it was suggested that a quantum system could be used to simulate some physical systems more efficiently than a UTM.

Many optimization and simulation problems are not solvable using UTMs. Because of this limitation, there is need in the art for computational devices capable of solving computational problems beyond the scope of UTMs. In the field of protein folding, for example, grid computing systems and supercomputers have been used to try to simulate large protein systems. See Shirts et al., 2000, Science 290, pp. 1903-1904, and Allen et al., 2001, IBM Systems Journal 40, p. 310. The NEOS solver is an online network solver for optimization problems, where a user submits an optimization problem, selects an algorithm to solve it, and then a central server directs the problem to a computer in the network capable of running the selected algorithm. See e.g., Dolan et al., 2002, SIAM News Vol. 35, p. 6. Other digital computer-based systems and methods for solving optimization problems can be found, for example, in Fourer et al., 2001, Interfaces 31, pp. 130-150. All these methods are limited, however, by the fact they utilize digital computers, which are UTMs, and accordingly, are subject to the limits of classical computing that inherently possess unfavorable scaling of solution time as a function of problem size.

### Persistent Current Coupler

FIG. 1A shows a schematic diagram of a controllable coupler 100. This coupler is a loop of superconducting material 101 interrupted by a single Josephson junction 102 and is used to couple a first qubit 110 and a second qubit 120 for use in an analog computer. First qubit 110 is comprised of a loop of superconducting material 111 interrupted by a compound Josephson junction 112 and is coupled to controllable coupler 100 through the exchange of flux 103 between coupler 100 and first qubit 110. Second qubit 120 is comprised of a loop of superconducting material 121 interrupted by a compound Josephson junction 122 and is coupled to controllable coupler 100 through the exchange of flux 104 between coupler 100 and second qubit 120. Loop of superconducting material 101 is threaded by flux 105 created by electrical current flowing through a magnetic flux inductor 130.

Flux 105 produced by magnetic flux inductor 130 threads loop of superconducting material 101 and controls the state of controllable coupler 100. Controllable coupler 100 is capable of producing a zero coupling between first qubit 110 and second qubit 120, an anti-ferromagnetic coupling between first qubit 110 and second qubit 120, and a ferromagnetic coupling between first qubit 110 and second qubit 120.

FIG. 1 B shows an exemplary two-pi-periodic graph 150 giving the relationship between the persistent current (I) flowing within loop of superconducting material 101 of controllable coupler 100 (Y-axis) as a function of flux (Φ_{X}) 105 from magnetic flux inductor 130 threading loop of superconducting material 101 and scaled with the superconducting flux quantum Φ₀ (X-axis).

Zero coupling exists between first qubit 110 and second qubit 120 when coupler 100 is set to point 160 or any other point along graph 150 with a similar slope of about zero of point 160. Anti-ferromagnetic coupling exists between first qubit 110 and second qubit 120 when coupler 100 is set to the point 170 or any other point along graph 150 with a similar positive slope of point 170. Ferromagnetic coupling exists between first qubit 110 and second qubit 120 when coupler 100 is set to point 180 or any other point along graph 150 with a similar negative slope of point 180.

Coupler 100 is set to states 160,170 and 180 by adjusting amount of flux 105 coupled between magnetic flux inductor 130 and loop of superconducting material 101. The state of coupler 100 is dependant upon the slope of graph 150. For dI/dΦₓ equal to approximately zero, coupler 100 is said to produce a zero coupling or non-coupling state where the quantum state of first qubit 110 does not interact with the state of second qubit 120. For dI/dΦₓ greater than zero, the coupler is said to produce an anti-ferromagnetic coupling where the state of first qubit 110 and the state of second qubit 120 will be dissimilar in their lowest energy state. For dI/dΦₓ less than zero, the coupler is said to produce a ferromagnetic coupling where the state of first state 110 and the state of second qubit 120 will be similar in their lowest energy state. From the zero coupling state with corresponding flux level 161, flux (Φ_{X}) 105 produced by magnetic flux inductor 130 threading loop of superconducting material 101 can be decreased to a flux level 171 to produce an anti-ferromagnetic coupling between first qubit 110 and second qubit 120 or increased to a flux level 181 to produce a ferromagnetic coupling between first qubit 110 and second qubit 120.

Examining persistent current 162 that exists at zero coupling point 160, with corresponding zero coupling applied flux 161, shows a large persistent current is coupled into first qubit 110 and second qubit 120. This is not ideal as there may be unintended interactions between this persistent current flowing through controllable coupler 100 and other components within the analog processor in which controllable coupler 100 exists. Both anti-ferromagnetic coupling persistent current level 172 and ferromagnetic coupling persistent current level 182 may be of similar magnitudes as compared to zero coupling persistent current level 162 thereby causing similar unintended interactions between the persistent current of coupler 100 and other components within the analog processor in which controllable coupler 100 exists. Anti-ferromagnetic coupling persistent current level 172 and ferromagnetic coupling persistent current level 182 may be minimized such that persistent current levels 172 and 182 are about zero during regular operations.

For further discussion of the persistent current couplers, see e.g., Harris, R., “Sign and Magnitude Tunable Coupler for Superconducting Flux Qubits”, arXiv.org: cond-mat/0608253 (2006), pp. 1-5, and Maassen van der Brink, A. et al., “Mediated tunable coupling of flux qubits,” New Journal of Physics 7 (2005) 230.

### BRIEF SUMMARY

In at least one embodiment, a coupling system includes an rf-SQUID having a loop of superconducting material interrupted by a compound Josephson junction; a magnetic flux inductor; a first mutual inductance coupling the rf-SQUID to a first qubit; a second mutual inductance coupling the rf-SQUID to a second qubit; and a third mutual inductance coupling the compound Josephson junction to the magnetic flux inductor.

In at least one embodiment, a method of controllably coupling a first qubit to a second qubit by an rf-SQUID having a loop of superconducting material interrupted by a compound Josephson junction includes coupling the first qubit to the rf-SQUID; coupling the second qubit to the rf-SQUID; coupling a magnetic flux inductor to the compound Josephson junction; and adjusting an amount of flux, produced by the magnetic flux inductor, threading the compound Josephson junction.

In at least one embodiment, a coupling system includes an rf-SQUID having a loop of superconducting material interrupted by a compound Josephson junction; and a first magnetic flux inductor configured to selectively provide a first magnetic flux inductor mutual inductance coupling the first magnetic flux inductor to the compound Josephson junction, wherein the loop of superconducting material positioned with respect to a first qubit to provide a first mutual inductance coupling the rf-SQUID to the first qubit and wherein the loop of superconducting material positioned with respect to a second qubit to provide a second mutual inductance coupling rf-SQUID to the second qubit. The coupling system may further include a second magnetic flux inductor configured to selectively provide a second magnetic flux inductor mutual inductance coupling the second magnetic flux inductor to the compound Josephson junction.

In at least one embodiment, a superconducting processor includes a first qubit; a second qubit; an rf-SQUID having a loop of superconducting material interrupted by a compound Josephson junction; and magnetic flux means for selectively providing inductance coupling the magnetic flux means to the compound Josephson junction, wherein the loop of superconducting material is configured to provide a first mutual inductance coupling the rf-SQUID to the first qubit and to provide a second mutual inductance coupling rf-SQUID to the second qubit. The magnetic flux means may take the form of a first magnetic flux inductor configured to provide a third mutual inductance selectively coupling the magnetic flux inductor to the compound Josephson junction. The magnetic flux means may further take the form of a second magnetic flux inductor configured to provide a fourth mutual inductance selectively coupling the second magnetic flux inductor to the compound Josephson junction.

### BRIEF DESCRIPTION OF THE SEVERAL VIEWS OF THE DRAWINGS

In the drawings, identical reference numbers identify similar elements or acts. The sizes and relative positions of elements in the drawings are not necessarily drawn to scale. For example, the shapes of various elements and angles are not drawn to scale, and some of these elements are arbitrarily enlarged and positioned to improve drawing legibility. Further, the particular shapes of the elements as drawn are not intended to convey any information regarding the actual shape of the particular elements, and have been solely selected for ease of recognition in the drawings.

FIG. 1A is a schematic diagram of a controllable coupler according to the prior art.

FIG. 1B is a graph of persistent current versus magnetic flux threading a loop of superconducting material of a controllable coupler according to the prior art.

FIG. 2A is a schematic diagram of an embodiment of a superconducting controllable coupler system.

FIG. 2B is a graph of persistent current versus magnetic flux threading a loop of superconducting material of a controllable coupler system.

FIG. 2C is a graph of persistent current versus magnetic flux threading a loop of superconducting material of a controllable coupler system.

FIG. 2D is a graph of persistent current versus magnetic flux threading a loop of superconducting material of a controllable coupler system.

FIG. 3 is a schematic diagram of a superconducting controllable coupler system according to one illustrated embodiment.

FIG. 4 is a schematic diagram of a superconducting controllable coupler system according to another illustrated embodiment.

### DETAILED DESCRIPTION OF THE INVENTION

A coupler 100 produces a non-zero persistent current when producing a zero coupling state 160 between a first qubit 110 and a second qubit 120. This non-zero persistent current generates flux offsets in qubits 110 and 120 which may be compensated for. Persistent current 162 generates a flux within the coupler which may thereby be unintentionally coupled into qubits 110 and 120. Qubits 110 and 120 must therefore be biased such that the unintentional flux does not effect the state of qubits 110 and 120. Also, while dI/dΦₓ is near zero, higher order derivatives may cause higher-order, non-negligible interactions which may be undesirable between first qubit 110 and second qubit 120.

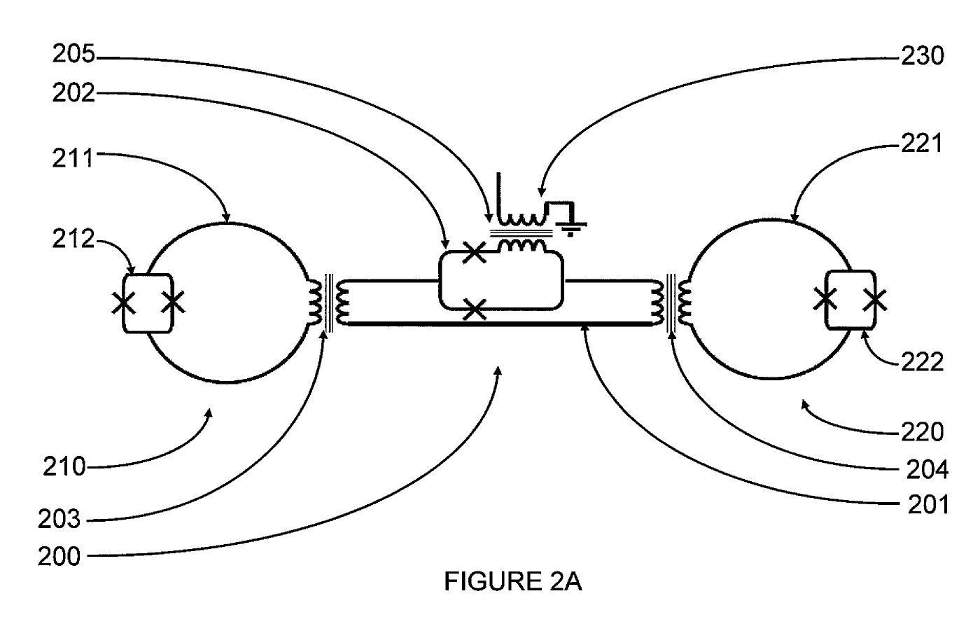

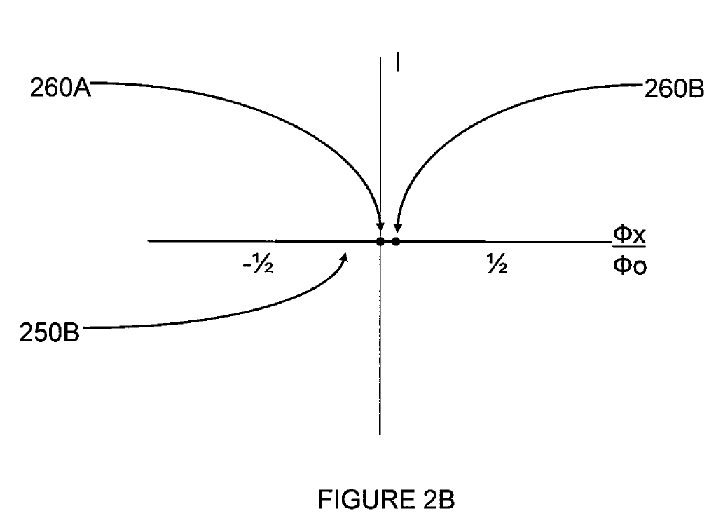

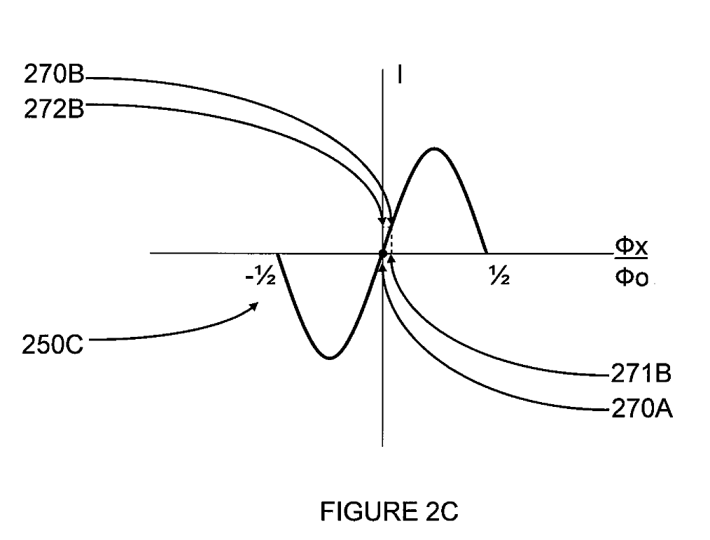

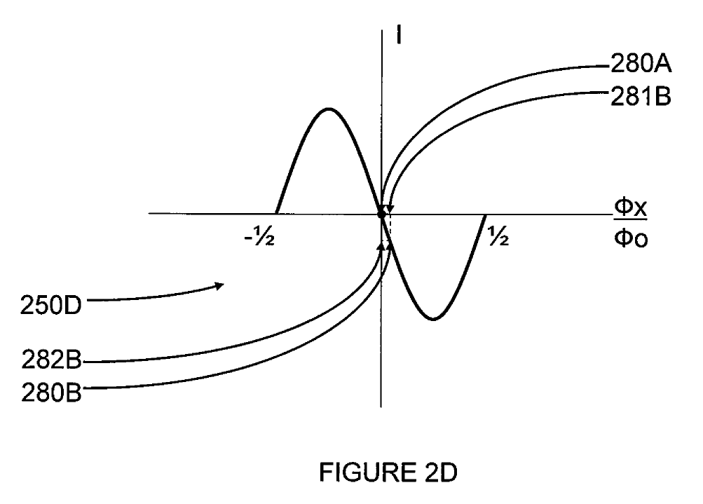

One embodiment of the present system, devices and methods is shown in the schematic diagram of FIG. 2A. A controllable coupler 200, (i.e., a loop of superconducting material 201 interrupted by a compound Josephson junction 202) is used to inductively couple a first qubit 210 and a second qubit 220 for use in an analog computer. In one embodiment, first qubit 210 is comprised of a loop of superconducting material 211 interrupted by a compound Josephson junction 212 and is coupled to controllable coupler 200 through the exchange of flux 203 between coupler 200 and first qubit 210. Second qubit 220 is comprised of a loop of superconducting material 221 interrupted by a compound Josephson junction 222 and is coupled to controllable coupler 200 through the exchange of flux 204 between coupler 200 and second qubit 220. Those of skill in the art appreciate other superconducting flux qubit designs may be chosen. Those of skill in the art appreciate that the qubit design of first qubit 210 may be of a different design than that of second qubit 220. Compound Josephson junction 202 is threaded by flux 205 created by current flowing through a magnetic flux inductor 230. Flux 205 produced by magnetic flux inductor 230 threads compound Josephson junction 202 of controllable coupler 200 and controls the state of controllable coupler 200.

In one embodiment, controllable coupler 200 is capable of producing a zero coupling between first qubit 210 and second qubit 220. To produce the zero coupling between first qubit 210 and second qubit 220, amount of flux 205 threading compound Josephson junction 202 is adjusted to be about (n+½)Φ₀, wherein n is an integer and (Do is the magnetic flux quantum. In one embodiment, controllable coupler 200 is capable of producing an anti-ferromagnetic coupling between first qubit 210 and second qubit 220. To produce the anti-ferromagnetic coupling between first qubit 210 and second qubit 220, amount of flux 205 threading compound Josephson junction 202 is adjusted to be about (2n)Φ₀, wherein n is an integer. In one embodiment, controllable coupler 200 is capable of producing a ferromagnetic coupling between first qubit 210 and second qubit 220. To produce the ferromagnetic coupling between first qubit 210 and second qubit 220, amount of flux 205 threading compound Josephson junction 202 is adjusted to be about (2n+1)Φ₀, wherein n is an integer. Those of skill in the art would appreciate amount of flux 205 threading compound Josephson junction 202 is a rough value and amounts of flux 205 threading compound Josephson junction 202 of comparable amounts will produce similar coupling states.

One of skill in the art would appreciate that a twist in loop of superconducting material 201 results in controllable coupler 200 producing an anti-ferromagnetic coupling between first qubit 210 and second qubit 220 when amount of flux 205 threading compound Josephson junction 202 is adjusted to be about (2n+1)Φ₀, wherein n is an integer and a ferromagnetic coupling between first qubit 210 and second qubit 220 when amount of flux 205 threading compound Josephson junction 202 is adjusted to be about (2n)Φ₀, wherein n is an integer.

FIG. 2B shows an exemplary two-pi-periodic graph 250B giving the relationship between the persistent current (I) flowing within loop of superconducting material 201 of controllable coupler 200 (Y-axis) and the amount of flux (Φ_{X}) threading loop of superconducting material 201 divided by Φ₀ (X-axis) wherein amount of flux 205 threading compound Josephson junction 202 is adjusted to be about (n+½)Φ₀, wherein n is an integer, such that zero coupling is produced by controllable coupler 200 between first qubit 210 and second qubit 220.

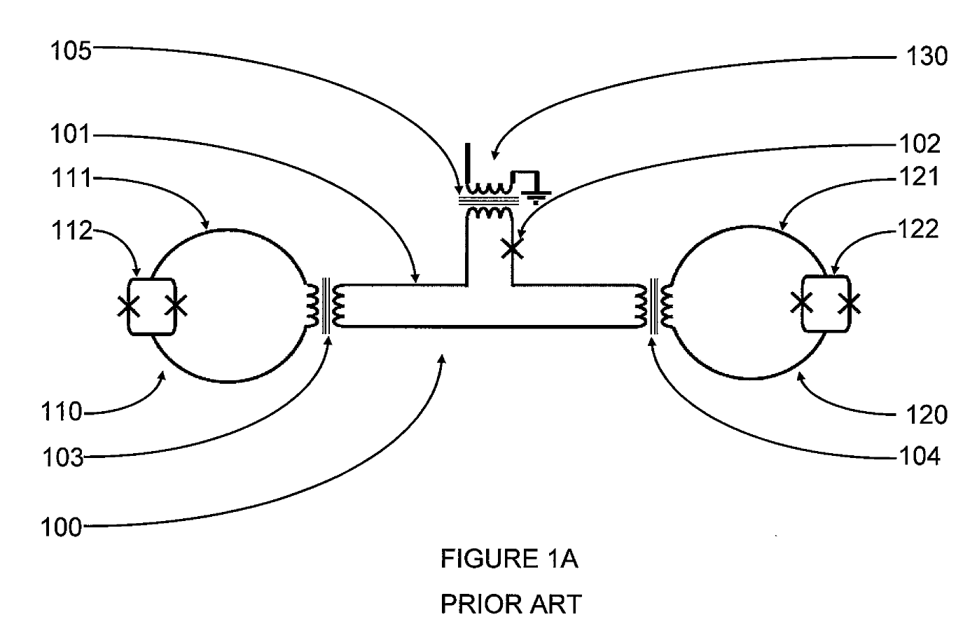

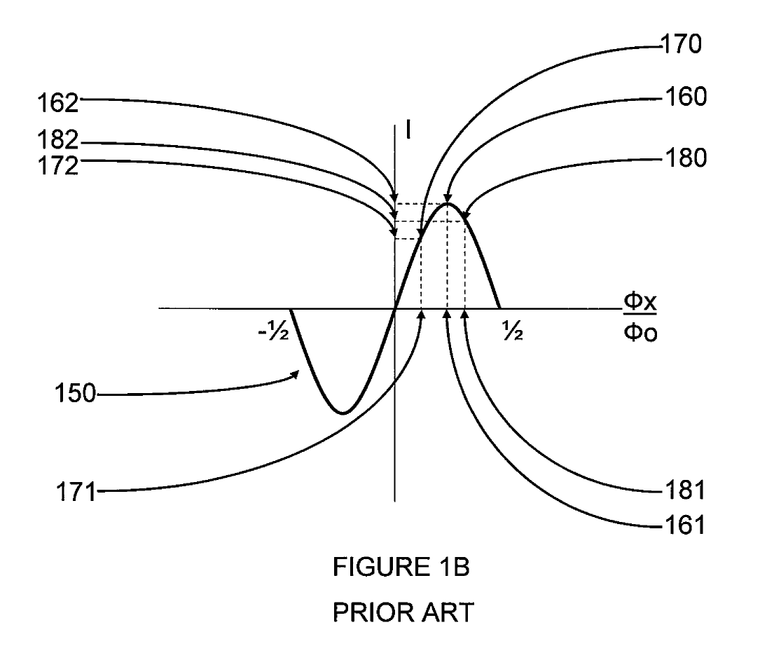

Point 260A identifies one possible operating point of controllable coupler 200 where there is no flux (Φ_{X}) threading loop of superconducting material 201 and a zero coupling is produced. Point 260B shows a second possible operating point of controllable coupler 200 where there is a non-zero amount of flux threading loop of superconducting material 201 and a zero coupling state is produced. The amount of flux may be from an external magnetic field that threads through loop of superconducting material 201, or the amount may be from the flux 205 intentionally or unintentionally produced by the magnetic flux inductor that threads loop of superconducting material 201 rather than compound Josephson junction 205. By applying an amount of flux 205 threading compound Josephson junction 202 of about (2n+1)Φ₀, graph 250B exhibits the zero coupling state that controllable coupler 200 produces between first qubit 210 and second qubit 220 for all values of flux threading loop of superconducting material 201. Little or no persistent current exists within loop of superconducting material 201 as seen by how closely graph 250B is to the zero persistent current value for all values of flux threading loop of superconducting material 201. This gives an improvement over controllable coupler 100 where a large persistent current 162 is present when the zero-coupling state is produced, as seen in FIG. 1B.

FIG. 2C shows an exemplary two-pi-periodic graph 250C giving the relationship between the persistent current (I) flowing within loop of superconducting material 201 of controllable coupler 200 (Y-axis) and the amount of flux (Φ_{X}) threading loop of superconducting material 201 divided by Φ₀ (X-axis) wherein amount of flux 205 threading compound Josephson junction 202 is adjusted to be about (2n)Φ₀, wherein n is an integer, such that an anti-ferromagnetic coupling is produced by controllable coupler 200 between first qubit 210 and second qubit 220.

Point 270A identifies one possible operating point of controllable coupler 200 where there is no flux (Φ_{X}) threading loop of superconducting material 201 and an anti-ferromagnetic coupling is produced. Point 270B shows a second possible operating point of controllable coupler 200 where an amount of flux 271B threading loop of superconducting material 201 and an anti-ferromagnetic coupling is produced. Flux 271B may be from an external magnetic field that threads through loop of superconducting material 201, or flux 271B may be from flux 205 produced by the magnetic flux inductor threads loop of superconducting material 201 rather than compound Josephson junction 205. By applying an amount of flux 205 threading compound Josephson junction 202 of about (2n)Φ₀ graph 250C exhibits the anti-ferromagnetic coupling state produced by controllable coupler 200 between first qubit 210 and second qubit 220 for all values of flux threading loop of superconducting material 201 where the slope of graph 250C is similar to that at points 270A and 270B. Persistent current 272B associated with operating point 270B is small.

FIG. 2D shows an exemplary two-pi-periodic graph 250D giving the relationship between the persistent current (I) flowing within loop of superconducting material 201 of controllable coupler 200 (Y-axis) and the amount of flux (Φ_{X}) threading loop of superconducting material 201 divided by Φ₀ (X-axis) wherein amount of flux 205 threading compound Josephson junction 202 is adjusted to be about (2n+1)Φ₀, wherein n is an integer, such that a ferromagnetic coupling is produced by controllable coupler 200 between first qubit 210 and second qubit 220.

Point 280A identifies one possible operating point of controllable coupler 200 where there is no flux (Φ_{X}) threading loop of superconducting material 201 and a ferromagnetic coupling is produced. Point 280B shows a second possible operating point of controllable coupler 200 where an amount of flux 281B threading loop of superconducting material 201 and a ferromagnetic coupling is produced. Amount of flux 281B may be from an external magnetic field that threads through loop of superconducting material 201, or the amount 281B may be from the flux 205 produced by the magnetic flux inductor threads loop of superconducting material 201 rather than compound Josephson junction 205. By applying an amount of flux 205 threading compound Josephson junction 202 of about (2n+1)Φ₀ graph 250D exhibits the ferromagnetic coupling state produced by controllable coupler 200 between first qubit 210 and second qubit 220 for all values of flux threading loop of superconducting material 201 where the slope of the graph 250D is similar to that at points 280A and 280B. Persistent current amount 282B associated with operating point 280B is small.

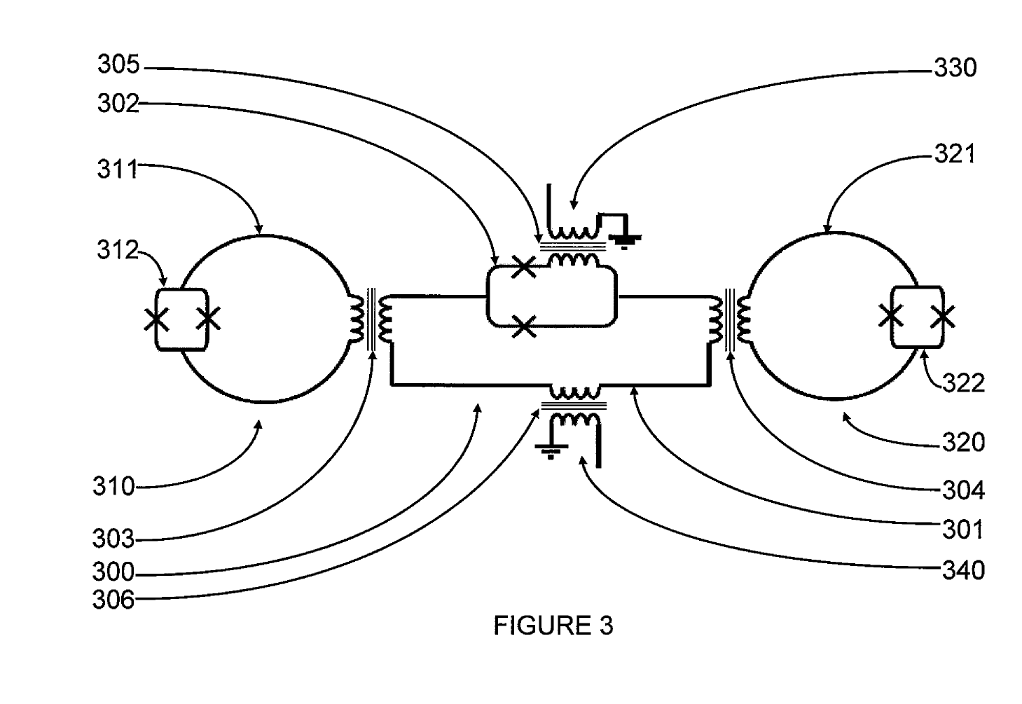

FIG. 3 shows a further embodiment of the present systems, devices, and devices. A controllable coupler 300, (i.e., a loop of superconducting material 301 interrupted by a compound Josephson junction 302) is used to inductively couple a first qubit 310 and a second qubit 320 for use in an analog computer. In this embodiment, first qubit 310 is comprised of a loop of superconducting material 311 interrupted by a compound Josephson junction 312 and is coupled to controllable coupler 300 through the exchange of flux 303 between coupler 300 and first qubit 310. Second qubit 320 is comprised of a loop of superconducting material 321 interrupted by a compound Josephson junction 322 and is coupled to controllable coupler 300 through the exchange of flux 304 between coupler 300 and second qubit 320. Those of skill in the art appreciate other qubit superconducting flux qubit designs may be chosen. Those of skill in the art appreciate that the qubit design of first qubit 310 may be of a different design than that of second qubit 320. Compound Josephson junction 302 is threaded by flux 305 created by current flowing through a magnetic flux inductor 330. Flux 305 produced by magnetic flux inductor 330 threads compound Josephson junction 302 of controllable coupler 300 and controls the state of controllable coupler 300. Loop of superconducting material 301 is threaded by flux 306 created by current flowing through a magnetic flux inductor 340. Flux 306 produced by the magnetic flux inductor 340 threads loop of superconducting material 301 of controllable coupler 320 and ensures that the net value of flux threading loop of superconducting material 301 is about zero. By ensuring the net value of flux threading loop of superconducting material 301 is about zero, a minimum amount of persistent current will be present within loop of superconducting material 301 during all states produced by controllable coupler 300.

In one embodiment, controllable coupler 300 is capable of producing a zero coupling between first qubit 310 and second qubit 320. To produce the zero coupling between first qubit 310 and second qubit 320, amount of flux 305 threading compound Josephson junction 302 is adjusted to be about (n+½)Φ₀, wherein n is an integer. In one embodiment, controllable coupler 300 is capable of producing an anti-ferromagnetic coupling between first qubit 310 and second qubit 320. To produce the anti-ferromagnetic coupling between first qubit 310 and second qubit 320, amount of flux 305 threading compound Josephson junction 302 is adjusted to be about (2n)Φ₀, wherein n is an integer. In one embodiment, controllable coupler 300 is capable of producing a ferromagnetic coupling between first qubit 310 and second qubit 320. To produce the ferromagnetic coupling between first qubit 310 and second qubit 320, amount of flux 305 threading compound Josephson junction 302 is adjusted to be about (2n+1)Φ₀, wherein n is an integer. Those of skill in the art would appreciate amount of flux 305 threading compound Josephson junction 302 is a rough value and amounts of flux 205 threading compound Josephson junction 302 of comparable amounts will produce similar coupling states.

As was seen by the design of controllable coupler 200, there may be a net flux threading loop of superconducting material 201 thereby producing coupling states 260B, 270B and 280B. With the use of magnetic flux inductor 340, flux 306 is controllably coupled into loop of superconducting material 301 of controllable coupler 300 to ensure that the net value of flux threading loop of superconducting material 301 is minimized such that coupling states 260A, 270A and 280A are produced by controllable coupler 300, thereby minimizing persistent current in loop of superconducting material 301 and thereby keeping the bias operations point in the centre of the linear regime of graphs 250C and 250D in order to minimize higher order derivatives which can cause unintended interactions between a first qubit 310 and a second qubit 320.

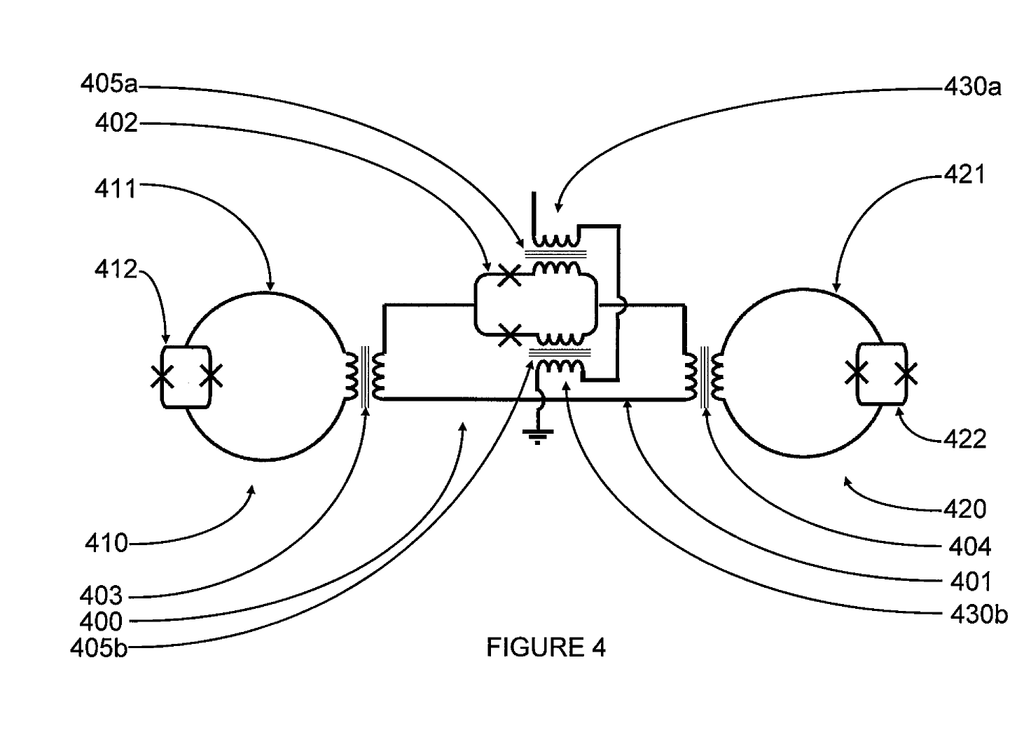

One embodiment of the present system, devices and methods is shown in the schematic diagram of FIG. 4. A controllable coupler 400, (i.e., a loop of superconducting material 401 interrupted by a compound Josephson junction 402) is used to inductively couple a first qubit 410 and a second qubit 420 for use in an analog computer. In one embodiment, first qubit 410 is comprised of a loop of superconducting material 411 interrupted by a compound Josephson junction 412 and is coupled to controllable coupler 400 through the exchange of flux 403 between coupler 400 and first qubit 410. Second qubit 420 is comprised of a loop of superconducting material 421 interrupted by a compound Josephson junction 422 and is coupled to controllable coupler 400 through the exchange of flux 404 between coupler 400 and second qubit 420. Those of skill in the art appreciate other superconducting flux qubit designs may be chosen. Those of skill in the art appreciate that the qubit design of first qubit 410 may be of a different design than that of second qubit 420. Compound Josephson junction 402 is threaded by flux 405a created by current flowing through a magnetic flux inductor 430a and flux 405b created by current flowing through a magnetic flux inductor 430b. Flux 405a produced by magnetic flux inductor 430a and flux 405b produced by magnetic flux inductor 430b thread compound Josephson junction 402 of controllable coupler 400 and the sum of flux 405a and flux 405b controls the state of controllable coupler 400.

We/I claim:

1. A coupling system comprising:
an rf-SQUID having a loop of superconducting material interrupted by a compound Josephson junction;
a magnetic flux inductor;
a first mutual inductance coupling the rf-SQUID to a first qubit;
a second mutual inductance coupling the rf-SQUID to a second qubit; and
a third mutual inductance coupling the compound Josephson junction to the magnetic flux inductor.

2. The coupling system of claim 1 wherein at least one of the first qubit and the second qubit is a superconducting flux qubit.

3. The coupling system of claim 1 wherein the magnetic flux inductor controls a coupling state of the coupling device.

4. The coupling system of claim 3 wherein the coupling state is produced and there exists a persistent current within the loop of superconducting material with a magnitude of about zero.

5. The coupling system of claim 3 wherein the coupling state of the coupling device is selected from the group of anti-ferromagnetic coupling, ferromagnetic coupling and zero coupling.

6. The coupling system of claim 1 further comprising:
a second magnetic flux inductor; and
a fourth mutual inductance coupling the loop of superconducting material to the second magnetic flux inductor.

7. The coupling system of claim 6 wherein the second flux transformer is capable of decreasing a persistent current within the loop of superconducting material during operation.

8. A method of controllably coupling a first qubit to a second qubit by an rf-SQUID having a loop of superconducting material interrupted by a compound Josephson junction, the method comprising:
coupling the first qubit to the rf-SQUID;
coupling the second qubit to the rf-SQUID;
coupling a magnetic flux inductor to the compound Josephson junction; and
adjusting an amount of flux, produced by the magnetic flux inductor, threading the compound Josephson junction.

9. The method of claim 8, further comprising:
coupling a second magnetic flux inductor to the loop of superconducting material; and
adjusting a second amount of flux, produced by the second magnetic flux inductor, threading the loop of superconducting material.

10. The method of claim 8 wherein at least one of the first qubit and the second qubit is a superconducting flux qubit.

11. The method of claim 8 wherein coupling the first qubit to the loop of superconducting material comprises:
threading magnetic flux produced by current flowing in the first qubit into the loop of superconducting material; and
threading magnetic flux produced by current flowing in the loop of superconducting material into the first qubit.

12. The method of claim 8 wherein coupling the second qubit to the loop of superconducting material comprises:
threading magnetic flux produced by current flowing in the second qubit into the loop of superconducting material; and
threading magnetic flux produced by current flowing in the loop of superconducting material into the second qubit.

13. The method of claim 8 wherein coupling a magnetic flux inductor to the compound Josephson junction comprises:
threading magnetic flux produced by current flowing through the magnetic flux inductor into the compound Josephson junction.

14. The method of claim 8 wherein adjusting the amount of flux, produced by the magnetic flux inductor, threading the compound Josephson junction comprises at least one of flowing more current through the magnetic flux inductor or flowing less current through the magnetic flux inductor.

15. The method of claim 8 wherein adjusting the amount of flux, produced by the magnetic flux inductor, threading the compound Josephson junction results in coupling the first qubit and the second qubit with a coupling selected from the group of anti-ferromagnetically coupling, ferromagnetically coupling and zero coupling.

16. A coupling system comprising:
an rf-SQUID having a loop of superconducting material interrupted by a compound Josephson junction; and
a first magnetic flux inductor configured to selectively provide a first magnetic flux inductor mutual inductance coupling the first magnetic flux inductor to the compound Josephson junction, wherein the loop of superconducting material positioned with respect to a first qubit to provide a first mutual inductance coupling the rf-SQUID to the first qubit and wherein the loop of superconducting material positioned with respect to a second qubit to provide a second mutual inductance coupling rf-SQUID to the second qubit.

17. The coupling system of claim 16, further comprising:
a second magnetic flux inductor configured to selectively provide a second magnetic flux inductor mutual inductance coupling the second magnetic flux inductor to the compound Josephson junction.

18. A superconducting processor comprising:
a first qubit;
a second qubit;
an rf-SQUID having a loop of superconducting material interrupted by a compound Josephson junction; and
magnetic flux means for selectively providing inductive coupling of the magnetic flux means to the compound Josephson junction, wherein the loop of superconducting material is configured to provide a first mutual inductance coupling the rf-SQUID to the first qubit and to provide a second mutual inductance coupling rf-SQUID to the second qubit.

19. The superconducting processor of claim 18 wherein at least one of the first qubit and the second qubit is a superconducting flux qubit.

20. The superconducting processor of claim 18 wherein the magnetic flux means includes a first magnetic flux inductor configured to selectively provide a third mutual inductance coupling the first magnetic flux inductor to the compound Josephson junction.

21. The superconducting processor of claim 20 wherein the magnetic flux means includes a second magnetic flux inductor configured to selectively provide a fourth mutual inductance coupling the second magnetic flux inductor to the compound Josephson junction.
